(19) United States
(12) Patent Application Publication
(10) Pub. No.: US 2010/0181669 A1
(43) Pub. Date: Jul. 22, 2010

(54) SEMICONDUCTOR DEVICE AND METHOD FOR MANUFACTURING THE SAME

(76) Inventor: Yasuhiko Tanaka, Osaka-shi (JP)

Correspondence Address: NIXON & VANDERHYE, PC, 901 NORTH GLEBE ROAD, 11TH FLOOR, ARLINGTON, VA, 22203, US

(21) Appl. No.: 12/690,400

(22) Filed: Jan. 20, 2010

(30) Foreign Application Priority Data
Jan. 21, 2009 (JP) 2009-010941

(51) Int. Cl. H01L 23/49; H01L 21/60

(52) U.S. Cl. 257/750; 438/618; 257/E23.024; 257/E21.507

(57) ABSTRACT

In order to improve a bonding reliability of a semiconductor device, in the semiconductor device, the wiring patterns on the substrate surface and the connection electrodes are electrically connected by face-down mounting. The connection electrodes are formed on the connecting surface of the semiconductor element and made from a conductive material, and a part of the wiring patterns has such a width that allows the connection electrodes formed on the part of said wiring patterns to have a fillet shape.

This Nonprovisional application claims priority under 35 U.S.C. §119(a) on Patent Application No. 2009-010941 filed in Japan on Jan. 21, 2009, the entire contents of which are hereby incorporated by reference.

### TECHNICAL FIELD

The invention relates to a semiconductor device and a manufacturing method thereof, in each of which a semiconductor element is connected in such a manner that its semiconductor element surface faces to a substrate on which wiring patterns are formed.

### BACKGROUND ART

Conventionally, a semiconductor element and a substrate are electrically connected through wire bonding. However, wire bonding requires that the ends of wires are located outside of the chip. This results in a big mounting size. In addition, the semiconductor element and the substrate are connected with a large connection distance therebetween. This leads to a big inductance, which makes it difficult to attain fast performance.

Under these circumstances, flip-chip mounting has been frequently employed in recent years. Flip-chip mounting is a mounting method in which connection electrodes used for bonding to the substrate are formed on input terminals (pads) provided on a connection surface of the semiconductor (semiconductor element surface), and then the connection surface and the surface of the substrate are disposed to confront each other so that the connection electrodes on the connection surface and the electrodes on the substrate (wiring patterns) are connected with each other. Since the connection distance between the semiconductor element and the substrate is short, semiconductor devices mounted by flip-chip mounting are more suitable for achieving fast performance in comparison to those mounted by wire-bonding mounting.

The mounting method, as represented by the aforementioned flip-chip mounting method, in which the connection surface of the semiconductor element and the surface of the substrate are disposed to confront each other, is generally called face-down mounting method. In the face-down mounting method, as illustrated in FIG. 18, the connection surface of the semiconductor element 302 is set downward so that the connection electrodes 303 formed on the input terminal (not illustrated) on the connection surface and the wiring patterns 311 formed on the substrate 310 are electrically connected. Therefore, in the case where solder is used for the connection electrodes 303, the connection electrodes 303 are pressed by the weight of the semiconductor element 302, so that the connection electrodes 303 are deformed into shapes like barrels (casks, spherical zones).

Here, in the semiconductor device 300, as illustrated in FIG. 19, heat stress due to a difference between linear coefficients of expansion of the substrate 310 and the semiconductor element 302 and shear stress that arises from external force such as oscillation are generated in the directions of the arrows illustrated in FIG. 19. It is known that, when such stresses are generated, they are concentrated on the vicinity of bond parts of the semiconductor element 302 and the connection electrodes 303 and of the substrate 310 and the connection electrodes 303. In addition, it is generally known that the barrel-shaped connection electrodes 303 are likely to be affected by stresses, because their contact angles are obtuse. Therefore, breaking of the bond part through stresses tends to occur, and consequently the barrel-shaped connection electrodes 303 have a problem in bonding reliability.

In consideration of this problem, Patent Literature 1 discloses a semiconductor device that is improved in its bonding reliability by enlarging a surface area of the bump electrodes (connection electrodes). In the semiconductor device 400 described in Patent Literature 1, as illustrated in FIG. 20, auxiliary (or dummy) bump electrodes 403b are disposed to surround array of the main bump electrodes 403a. Consequently, the total number of bump electrodes 403 per chip (semiconductor element) 402 increases, which leads to a distribution of the shear stress and the like over such a larger number of electrodes. This realizes the semiconductor device 400 with a high bonding reliability between the printed circuit substrate (not illustrated) and the bump electrodes 403 and between the chip 402 and the bump electrodes 403.

Also, Patent Literature 2 discloses a semiconductor device that improves its bonding reliability by forming solder bumps (connection electrodes) in fillet shape with acute contact angles. It is known that fillet-shaped solder bumps mitigate the concentration of stress on the vicinity of the bond parts and thus can improve bonding reliability. In the semiconductor device 500 of Patent Literature 2, as illustrated in FIG. 21, the solder bumps 503 are formed in fillet shape by widening a distance between a printed-wiring substrate (substrate) 510 and a chip 502 to some extent with the use of the height control pins 507. By means of this, a semiconductor device 500 with a high bonding reliability is realized, wherein breaking of bond parts through stress is not likely to occur.

### Citation List

Patent Literature 1

Japanese Patent Application Publication, Tokukaihei, No. 10-12620 A (Publication Date: Jan. 16, 1998)

Patent Literature 2

Japanese Patent Application Publication, Tokukaisho, No. 62-139386 A (Publication Date: Jun. 23, 1987)

### SUMMARY OF INVENTION

### Technical Problem

However, in the semiconductor device 400 described in Patent Literature 1, it is necessary that the auxiliary bump electrodes 403b be formed in addition to the main bump electrodes 403a. Therefore, the increase of the total number of the bump electrodes 403 involves increase in the raw material for the bump electrodes 403 and gain in the weight of the semiconductor device 400. Moreover, since the amount of solder used for the bump electrodes 403a and 403b respectively are not even, the forming process of the bump electrodes 403 involves more complexity. In addition, when the composition of the auxiliary bump electrodes 403b is different from that of the main bump electrodes 403a, there is a problem that the forming process of the bump electrodes 403 is accompanied by an addition of a process.

Furthermore, in the semiconductor device 500 described in Patent Literature 2, since the solder bumps 503 are formed in fillet shape, it is necessary to add height control pins 507 that penetrate the substrate 510. Therefore, there are problems that the number of components increases and that additional steps such as passing the height control pins 507 through the substrate 510 is involved.

As stated above, the conventional technologies are accompanied by the increase of raw material, components, process or the others. Therefore, there are problems of the increase of manufacturing costs of semiconductor devices and extension of the manufacturing lead time.

This invention is made in view of the above-mentioned conventional problems, and an object thereof is to provide a semiconductor device with a high bonding reliability without involving increase of raw material, components, process or the others. Another object of the invention is to provide a manufacturing method of the above semiconductor device.

### Solution to Problem

A semiconductor device of the present invention is configured such that in which wiring patterns on a substrate and connection electrodes are electrically connected by face-down mounting, the connection electrodes being made from a conductive material and formed on a connecting surface of a semiconductor element. In order to attain the object, the semiconductor device of the present invention is configured such that a part of said wiring patterns has such a width that allows the connection electrodes formed on the part of said wiring patterns to have a fillet shape.

According to the invention, by configuring the width of a part of the wiring patterns as described above, fillet-shaped connection electrodes that are not likely to be affected by stress are formed on the wiring patterns.

As a result, it is possible to realize a semiconductor device having a high bonding reliability without increasing raw material, components, process and the others.

For a fuller understanding of the nature and advantages of the invention, reference should be made to the ensuing detailed description taken in conjunction with the accompanying drawings.

### ADVANTAGEOUS EFFECTS OF INVENTION

The semiconductor device of the present invention has, as described above, a structure in which the width of a part of the wiring patterns is configured in such a manner that fillet-shaped connection electrodes are formed on the wiring patterns.

Therefore, it brings about an effect that a semiconductor device having high bonding reliability and a manufacturing method thereof can be provided without involving increase of raw material, components or process and the others.

### BRIEF DESCRIPTION OF DRAWINGS

FIG. 1 is a cross-sectional view of a semiconductor device according to one embodiment of the invention, illustrating that a semiconductor element and wiring patterns on a substrate are connected via connection electrodes some of which are fillet-shaped.

FIG. 2(a) is a cross-sectional view illustrating the substrate constituting the semiconductor device illustrated in FIG. 1.

FIG. 2(b) is a cross-sectional view illustrating the substrate constituting the semiconductor device illustrated in FIG. 1.

FIG. 3(a) is a cross-sectional view illustrating the semiconductor element and connection electrodes constituting the semiconductor device illustrated in FIG. 1.

FIG. 3(b) is a cross-sectional view illustrating a semiconductor element and a connection electrode constituting the semiconductor device illustrated in FIG. 1.

FIG. 3(c) is a cross-sectional view illustrating a semiconductor element and a connection electrode constituting the semiconductor device illustrated in FIG. 1.

FIG. 4 is an enlarged cross-sectional view illustrating a peripheral corner part of the semiconductor element in the semiconductor device illustrated in FIG. 1.

FIG. 5 is an enlarged cross-sectional view illustrating a connection electrode of a semiconductor device.

FIG. 6(a) is a plan view illustrating an example of the positional distribution of the arrangement of barrel-shaped and fillet-shaped connection electrodes on the connection surface of the semiconductor element.

FIG. 6(b) is a plan view illustrating an example of the positional distribution of the arrangement of barrel-shaped and fillet-shaped connection electrodes on the connection surface of the semiconductor element.

FIG. 7 is a cross-sectional view illustrating a module including a plurality of semiconductor elements, a substrate and electronic components.

FIG. 8 is a view illustrating an arrangement of connection electrodes bonding two semiconductor elements to a substrate.

FIG. 9 is a cross-sectional view illustrating a semiconductor device, wherein a semiconductor element and another semiconductor element are bonded by connection electrodes.

FIG. 10 is a cross-sectional view illustrating steps of a manufacturing process of a substrate.

FIG. 11 is a plan view of a substrate on which wiring patterns are formed.

FIG. 12 is a cross-sectional view illustrating how to mount a semiconductor element on a substrate.

FIG. 13 is a cross-sectional view illustrating how to bond a substrate and a semiconductor element by heating method.

FIG. 14 is a cross-sectional view illustrating a substrate and a semiconductor element to which flux is applied.

FIG. 15 is a cross-sectional view illustrating how to introduce resin between a substrate and a semiconductor element.

FIG. 16 is a cross-sectional view illustrating how to perform plasma processing to a substrate and a semiconductor element.

FIG. 17 is a cross-sectional view illustrating a part of a semiconductor device, showing an equilibrium condition between gravity of the semiconductor element and a surface tension of solder or the like of the bond part.

FIG. 18 is a cross-sectional view illustrating a semiconductor device according to a conventional technology in which a semiconductor element and a substrate are flip-chip connected.

FIG. 19 is a cross-sectional view illustrating shear stress affecting the flip-chip connected bond part of the semiconductor device, accompanied by its partial enlarged view.

FIG. 20 is a cross-sectional view illustrating a conventional semiconductor device in which dummy bumps are disposed at the periphery.

FIG. 21 is a cross-sectional view illustrating a conventional semiconductor device in which height control pins that go through the substrate are disposed.

### DESCRIPTION OF EMBODIMENTS

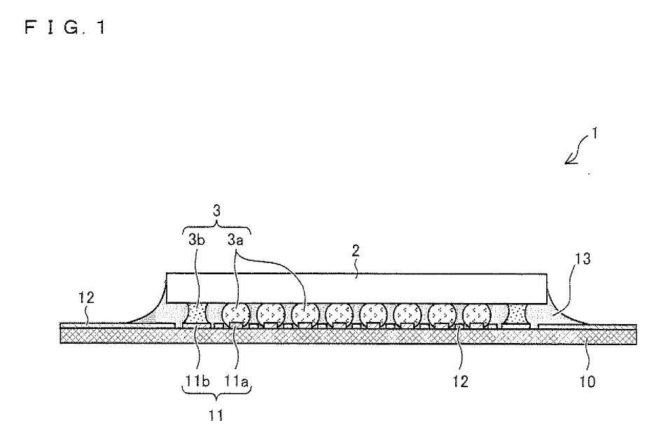

One embodiment of the invention is described as below with reference to FIGS. 1 to 17.

FIG. 1 is a cross-sectional view illustrating a semiconductor device 1 according to the embodiment, and it is illustrated that a semiconductor element 2 and wiring patterns on a substrate 10 are connected via connection electrodes 3, some of which are fillet-shaped. As illustrated in FIG. 1, the semiconductor device 1 employs a so-called face-down mounting method, wherein the semiconductor element 2 is disposed on the substrate 10 so that their connection surfaces confront to each other and are bonded. In the semiconductor device 1, an input terminal (pad: not illustrated) of the semiconductor element 2 and the wiring patterns 11 on the substrate 10 are electrically connected via the connection electrodes 3. In addition, solder resist 12 is formed on that part of the substrate 10 where no wiring patterns 11 are formed. This prevents the connection electrodes 3 from adhering that part of the substrate 10 where no wiring patterns 11 are formed. Moreover, encapsulation resin 13 fills a gap between the semiconductor element 2 and the substrate 10.

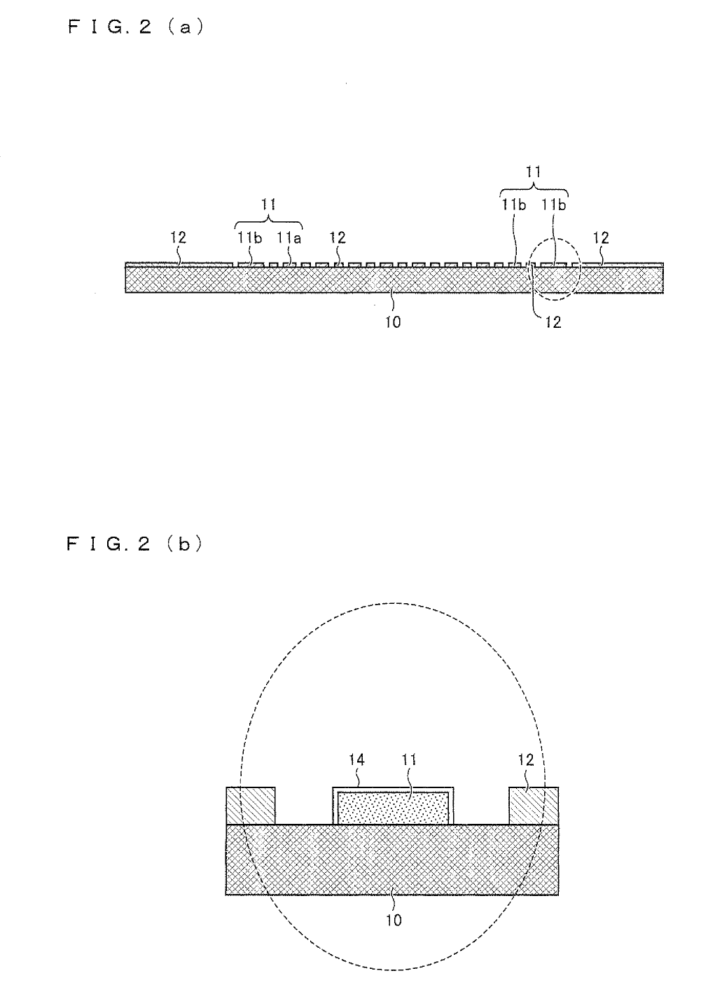

FIG. 2(a) and FIG. 2(b) are cross-sectional views illustrating the substrate 10 constituting the semiconductor device 1. The substrate 10 may be a phenol substrate, a paper-epoxy substrate, a glass composite substrate, a glass-epoxy substrate, a Teflon (Registered Trademark) substrate, an alumina substrate, a composite substrate or the like.

As illustrated in FIG. 2(a), the wiring patterns 11 and the solder resist 12 are formed on the substrate 10.

The wiring patterns 11 are made of a conductive material, and are formed by patterning a metal film made of copper or the like by e.g. photolithography. In addition, as illustrated in FIG. 2(b), a surface coating material 14 is formed on a surface of the wiring patterns 11. In terms of its composition, the surface coating material 14 is Sn, Au, Ni, Cu, lead-free solder, solder, organic solderability preservative and/or the like, and may be formed by plating, deposition, printing, dipping, or the like. Furthermore, the surface coating material 14 may have a structure made from any one of these materials or a layered structure made from any ones of these materials.

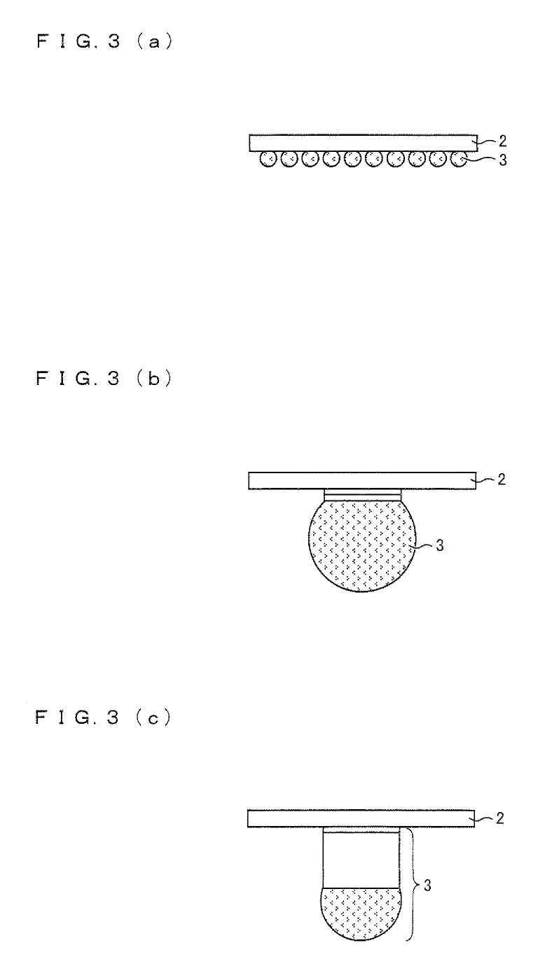

FIGS. 3(a) to FIGS. 3(c) are cross-sectional views illustrating the semiconductor element 2 and the connection electrodes 3 constituting the semiconductor device 1. As illustrated in FIG. 3(a), the connection electrodes 3 are bonded to the input terminals (not illustrated) on the connection surface of the semiconductor element 2. The connection electrodes 3 are made of a conductive material, such as solder, lead-free solder or the like. In addition, the connection electrodes 3 may be formed by, for example, plating, printing, deposition, ball placement method or the others. Furthermore, as illustrated in FIG. 3(b) or FIG. 3(c), the connection electrodes 3 may have a structure made of any one of the materials or a layered structure of any ones of materials.

The solder resist 12 is constituted by a thermosetting epoxy resin film or the like and prevents the constituent of the connection electrodes 3 from being adhered to the substrate 10 to which the connection electrodes 3 are not bonded.

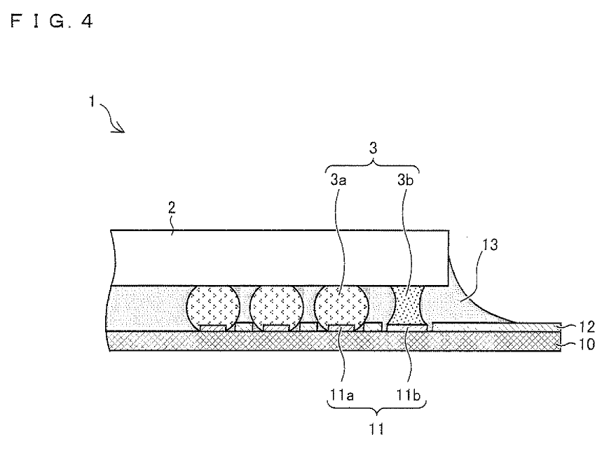

FIG. 4 is an enlarged cross-sectional view illustrating a peripheral corner part of the semiconductor element 2 in the semiconductor device 1 illustrated in FIG. 1. As illustrated in FIG. 4, the semiconductor device 1 is configured such that barrel-(cask-, spherical-zone-) shaped connection electrodes 3a are formed on the normal wiring patterns 11a. On the other hand, on the wiring patterns 11b at the peripheral corner part of the semiconductor element 2, a fillet-shaped connection electrode 3b is formed.

This results from that the wiring patterns 11b bonded to the fillet-shaped connection electrodes 3b formed at the peripheral corner parts of the semiconductor element 2 is broader in width than the normal wiring patterns 11a. The fillet-shaped connection electrodes 3b are less likely to be affected by heat stress and shear stress than the barrel-shaped connection electrodes 3a. Therefore, it is possible to enhance bonding reliability of the semiconductor device 1 by preventing the respective bond parts of the semiconductor element 2 and the fillet-shaped connection electrodes 3b and of the substrate 10 and the fillet-shaped connection electrodes 3b from breaking.

Hereinafter, how to form the fillet-shaped connection electrodes 3b is described in detail.

In the semiconductor device 1, in order to form the fillet-shaped connection electrodes 3b, the wiring patterns 11b are formed with a broader width in comparison to the normal wiring patterns 11a.

Therefore, in the semiconductor device 1, the fillet-shaped connection electrodes 3b are formed on the wiring patterns 11b by configuring the width of the wiring patterns 11b to be broad with use of e.g. below-mentioned formulas. Specifically, for the semiconductor device 1, the width of the wiring patterns 11b is configured in accordance with the following method.

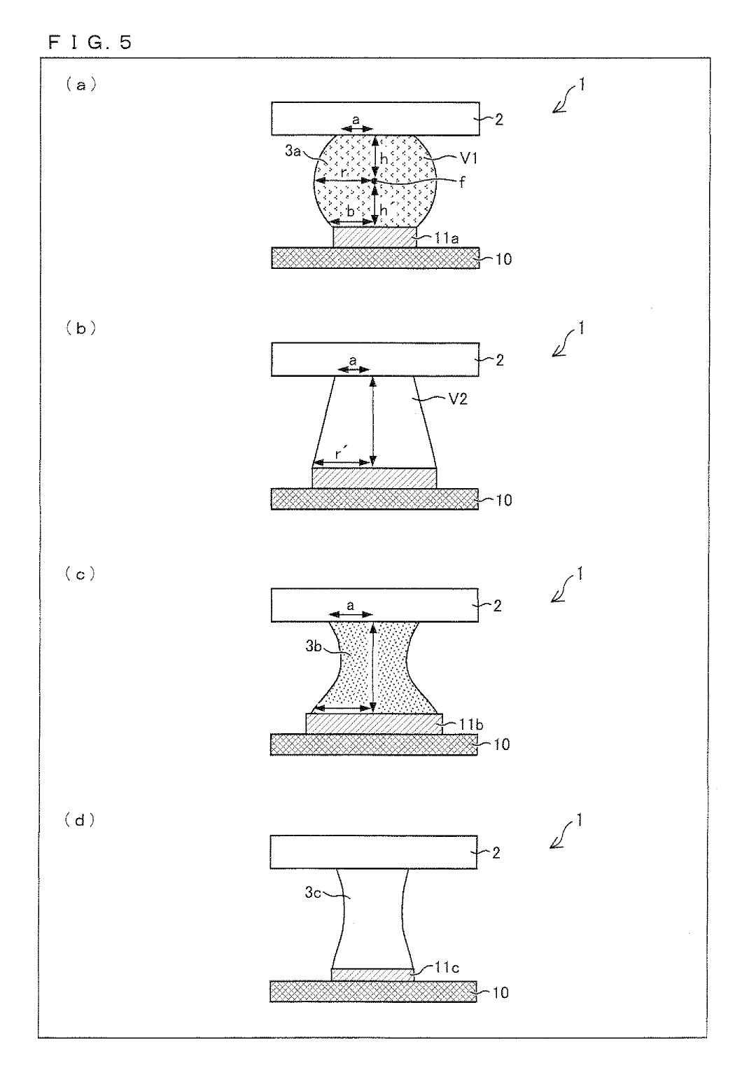

FIG. 5 is an enlarged cross-sectional view illustrating the connection electrode 3 of the semiconductor device 1. In the semiconductor device 1, the barrel-shaped connection electrode 3a illustrated in (a) of FIG. 5 and the circular truncated cone illustrated in (b) of FIG. 5 are identical in height, in radius of their top surfaces, and in volume. Therefore, it is possible to calculate a diameter 2r′ of a bottom surface of the circular truncated cone based on them. To be specific, the diameter 2r′ of the bottom surface of the circular truncated cone can be calculated by using the below-mentioned formulas.

First, volume V1 of the barrel-shaped connection electrode 3a illustrated in (a) of FIG. 5 is calculated by using the following Formula 1.

V1=[πh/6×(3a²+3r²+h²)]+[πh′/6×(3b²+3r²+h′²)] Formula 1

a: Radius of the top surface of the barrel-shaped connection electrode 3a (radius of the boundary face between the barrel-shaped connection electrode 3a and the semiconductor element 2)

b: Radius of the bottom surface of the barrel-shaped connection electrode 3a (radius of the boundary face between the barrel-faced connection electrode 3a and the wiring patterns 11a)

f: Center of gravity of the barrel-shaped connection electrode 3a

h: Distance from the center of gravity f to the top surface

h′: Distance from the center of gravity f to the bottom surface

r: Radius of the barrel-shaped connection electrode 3a

Next, since the barrel-shaped connection electrode 3a illustrated in (a) of FIG. 5 and the circular truncated cone illustrated in (b) of FIG. 5 have the same height and radius of the top surface, volume V2 of the circular truncated cone can be represented as the following Formula 2, when the radius of the bottom surface of the circular truncated cone is r′.

V2=(h+h′)/3(bottom area πr′²+top area πa²+πar′) Formula 2

Furthermore, because the volume V1 of the barrel-shaped connection electrode 3a and the volume V2 of the circular truncated cone are identical, the radius r′ of the bottom surface of the circular truncated cone can be calculated by substituting the Formula 1 and the Formula 2 for the following Formula 3.

V1=V2 Formula 3

Based on the radius r′ of the bottom surface of the circular truncated cone calculated as above, the width of the wiring patterns 11b illustrated in (c) of FIG. 5 is configured to be equal to or greater than twice the size of the radius r′ of the bottom surface of the circular truncated cone. This makes it possible to give a fillet shape to the connection electrode 3b formed on the wiring patterns 11b.

In addition, in the semiconductor device 1, the wiring patterns 11b are formed at the peripheral corner parts of the semiconductor element 2, as a result of which the fillet-shaped connection electrodes 3b are formed at the peripheral corner parts.

Also, a part of the wiring patterns 11 on the substrate 10 may be lower in height than the normal wiring patterns 11a, for forming the fillet-shaped electrodes 3c on said configured wiring patterns 11.

As illustrated in (d) of FIG. 5, wiring patterns 11c having the same width as and a lower height than the normal wiring patterns 11a are formed. This makes it possible to form the fillet-shaped connection electrode 3c on the wiring patterns 11c.

In addition, by configuring the width and height of a part of the wiring patterns 11, fillet-shaped connection electrodes may be formed.

Moreover, for example, by providing a concave portion on the top face of a part of the wiring patterns 11, the fillet-shaped connection electrode 3b may be formed on said wiring patterns.

Thus, according to this embodiment, by configuring at least one of the width and the height of the wiring patterns 11 at a desired position e.g. as described above, the fillet-shaped connection electrodes 3b (3c) can be formed on the configured wiring patterns 11b (11c).

Therefore, the fillet-shaped connection electrode 3b is formed at any position, and the fillet-shaped connection electrodes 3b can be formed at a desired position.

It is desirable that the position where the fillet-shaped connection electrodes 3b are formed be the peripheral corner parts of the semiconductor element 2, as can be seen in the semiconductor device 1. The peripheral corner parts of the semiconductor element 2 are the parts that are affected by stress the most. Therefore, by forming the fillet-shaped connection electrodes 3b there, breaking of the bond parts can effectively be prevented. This is because the bonding reliability of the semiconductor device 1 can be enhanced thereby.

As described above, it is possible to form the fillet-shaped connection electrodes 3b of the semiconductor device 1 by merely altering the form of a part of the wiring patterns 11. Therefore, according to this embodiment, no additional processes and components are required, and the semiconductor device 1 with a high bonding reliability can be realized without involving the increase of manufacturing costs and the extension of the manufacturing lead time.

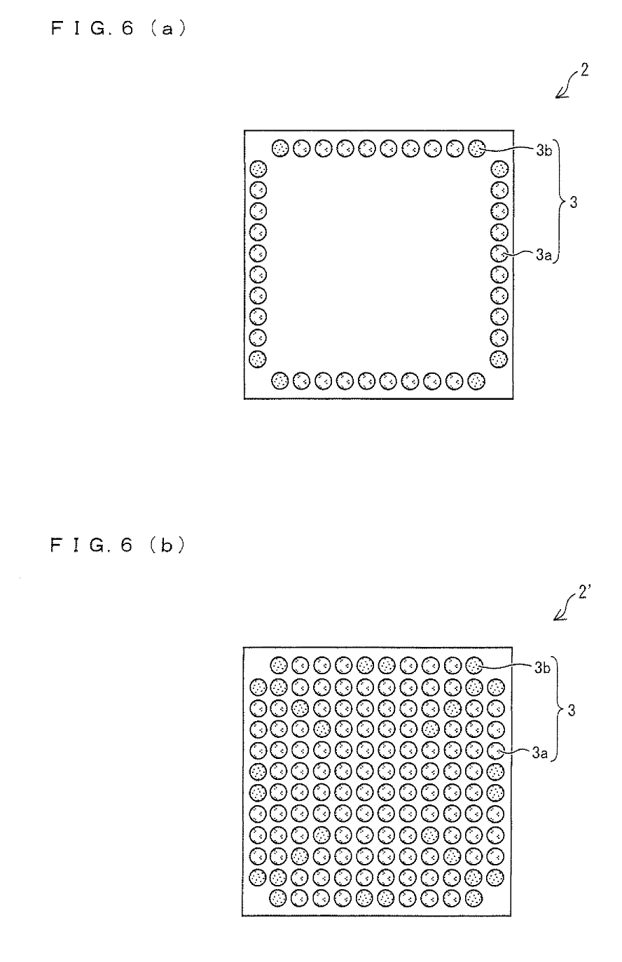

FIG. 6(a) and FIG. 6(b) are plan views illustrating examples of the position distribution of the arrangement of the barrel-shaped and fillet-shaped connection electrodes 3 on the connection surface of the semiconductor element 2. In the case of a peripheral layout, as illustrated in FIG. 6(a), the fillet-shaped connection electrodes 3b are preferably formed at the peripheral corner parts of the semiconductor element 2. However, the position where the fillet-shaped connection electrodes 3b are to be formed is not limited thereto. The connection electrodes 3 electrically connect the substrate 10 and the semiconductor element 2, and the number of their output signals as well as their form when arranged are determined according to what electrical function the semiconductor element 2 has. Thus, it is desirable that the positions where the fillet-shaped connection electrodes 3b are formed be altered as needed.

Meanwhile, in the case of an area-array layout, as illustrated in FIG. 6(b), it is desirable to form the fillet-shaped connection electrodes 3b at any parts of the peripheral columns and rows in addition to the peripheral corner parts of the semiconductor chip 2′.

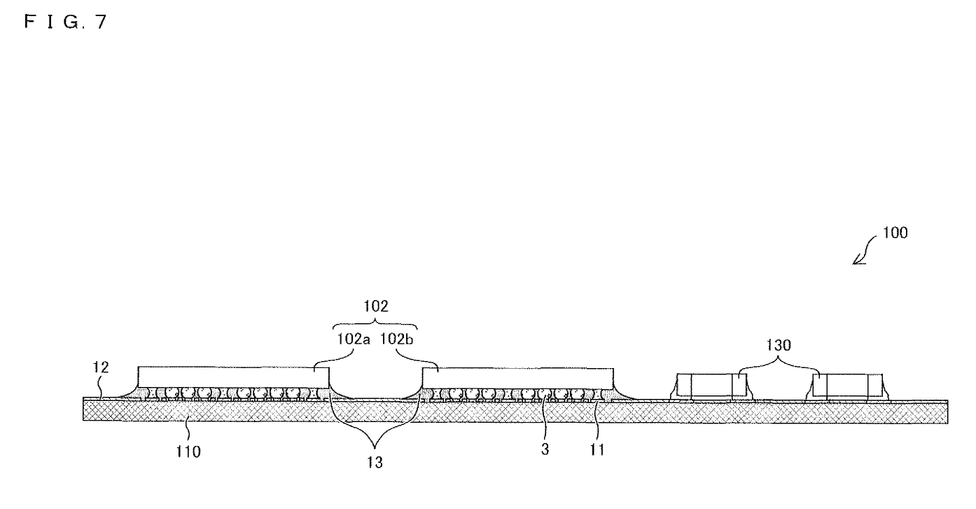

FIG. 7 is a cross-sectional view illustrating a module including a plurality of semiconductor elements, a substrate and discrete electronic components. As illustrated in FIG. 7, the semiconductor device 100 has a module configuration in which a semiconductor element 102a, another semiconductor element 102b, and two electronic components 130 are mounted on a substrate 110. The semiconductor element 102a and the another semiconductor element 102b have different electrical functions. Mounting the two semiconductor elements 102a, 102b and the two electronic components 130 on one substrate 110 makes it possible to reduce the number of the semiconductor device (substrate), resulting in that the entire module can be downsized.

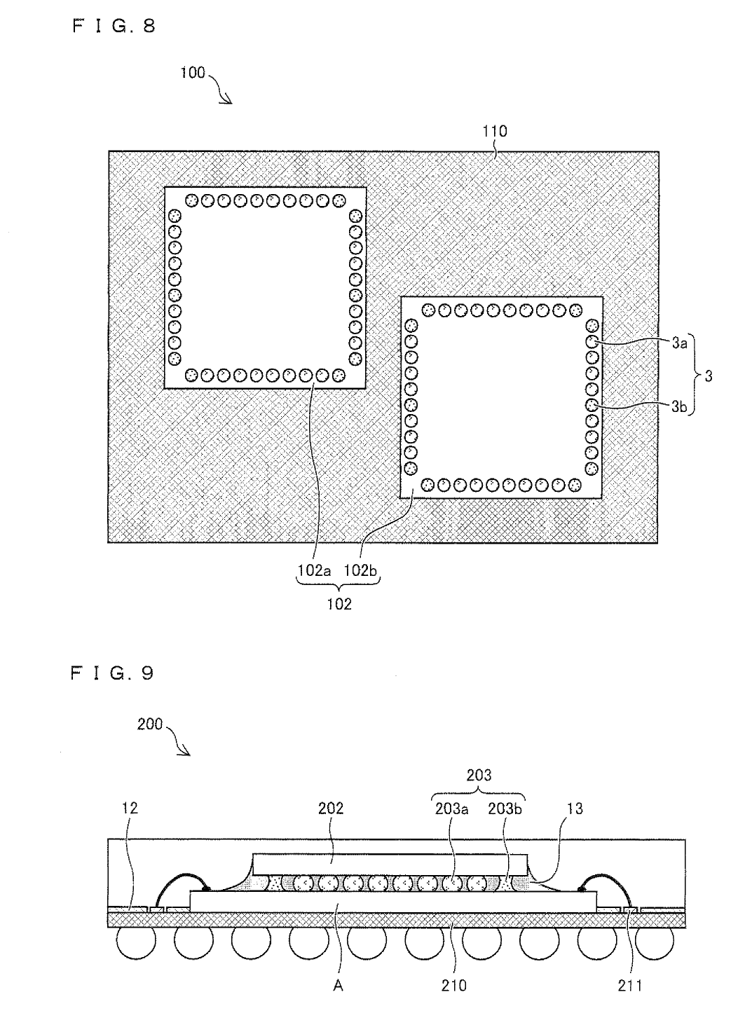

FIG. 8 is a drawing illustrating the arrangement of the connection electrodes 3 bonding the respective semiconductor elements 102a, 102b and the substrate 110 when the two semiconductor elements 102a and 102b are bonded. For example, when only one semiconductor element 102a is bonded, the shear stress that arises from the difference between linear coefficients of expansion of the substrate 110 and the semiconductor element 102a is applied to the peripheral corner parts of the semiconductor element 102a the most. However, when two or more semiconductor elements 102a and 102b are bonded, depending upon their positions, the respective semiconductor elements 102a and 102b may be affected by the adjacent semiconductor elements 102a and 102b.

For example, as illustrated in FIG. 8, when the semiconductor elements 102a and 102b are bonded to the substrate 110 in such a manner that the semiconductor elements 102a and 102b are aligned on one of the diagonal lines on the substrate 110, expansion and contraction of the substrate 110 along this diagonal line are inhibited. As a result, in some cases, a warp may be generated along the other diagonal line on the substrate 110. Then, a big shear stress due to the warp is applied to the connection electrodes 3 disposed on the other diagonal line and on the extended lines of the peripheral edges of the adjacent semiconductor elements 102a and 102b.

Consequently, as illustrated in FIG. 8, in the semiconductor device 100, it is desirable that the fillet-shaped connection electrodes 3b be formed not only at the peripheral corner parts of the semiconductor elements 102a and 102b but also on the extended lines of the peripheral edges of the adjacent semiconductor elements 102a and 102b where a big shear stress is applied.

FIG. 9 is a cross-sectional view illustrating the semiconductor device 200, wherein a semiconductor element 202 and a semiconductor element A are bonded by connection electrodes 203. The aforementioned semiconductor devices 1 and 100 have a structure in which the connection electrodes of the semiconductor element and the wiring patterns of the substrate are bonded. On the contrary, as illustrated in FIG. 9, in the semiconductor device 200, the semiconductor element 202 and the semiconductor element A are bonded by the connection electrodes 203. Even in this case, it is possible to form the connection electrodes 203 at any positions as fillet-shaped connection electrodes 203b by configuring the diameter of the boundary face between either one of the semiconductor elements 202 or A and its connection electrode 203 (diameter of a pad on the semiconductor element 202 or A) with use of the above-mentioned formulas.

Next, a manufacturing method of the semiconductor device 1 is described. It is to be noted that the description of the manufacturing method of the semiconductor element 2 is omitted here, because it can be manufactured by using a widely known method.

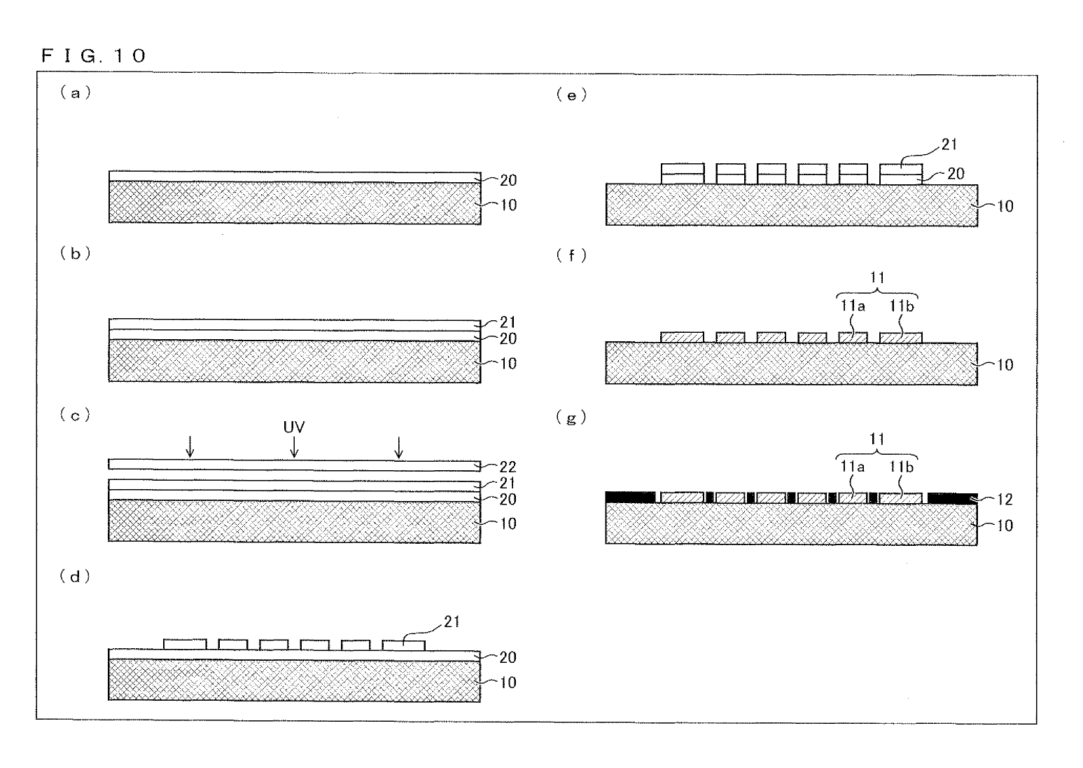

First, the manufacturing method of the substrate 10 is described. FIG. 10 is a cross-sectional view illustrating the respective manufacturing processes of the substrate 10. On the surface of the substrate 10, as illustrated in (a) of FIG. 10, a metal film 20 such as copper foil is formed. It should be noted that the kind of the substrate 10 to be used is not particularly limited, and the substrate 10 may be a phenol substrate, a paper-epoxy substrate, a glass composite substrate, a glass-epoxy substrate, a Teflon substrate, an alumina substrate, a composite substrate or the others.

For the formation of the wiring patterns 11, a method such as “photolithography”, in which light is illuminated through a photomask, may be employed. First, as illustrated in (b) of FIG. 10, a photoresist (photosensitizing agent) 21 is applied to the surface of the metal film 20 on the substrate 10. The method of application is not particularly limited: for example, by dropping the photoresist 21 in liquid form onto the surface of the substrate 10 mounted on an applicator and then spinning it at a high speed, it is possible to coat the surface with a thickness of ca. 1 micron.

Subsequently, as illustrated in (c) of FIG. 10, light is illuminated through a photomask 22 on the wiring substrate 10 to which photoresist 21 is applied so as to transfer the wiring patterns 11 on the photoresist 21. Specifically, the photomask 22 is accurately positioned onto the wiring substrate 10, and ultra-violet light is irradiated through the photomask 22 by a stepper (not illustrated). By means of this, ultra-violet light is transmitted only at the parts that are not masked by the photomask 22, and the exposed photoresist 21 is changed chemically.

Here, for the purpose of forming the fillet-shaped connection electrodes 3b, the photomask 22 is formed in such a manner that, in the wiring patterns 11 to be transcribed on the surface of the photoresist 21, the width of the wiring patterns 11 at an intended position be greater than the value calculated in accordance with the above-mentioned Formula 3.

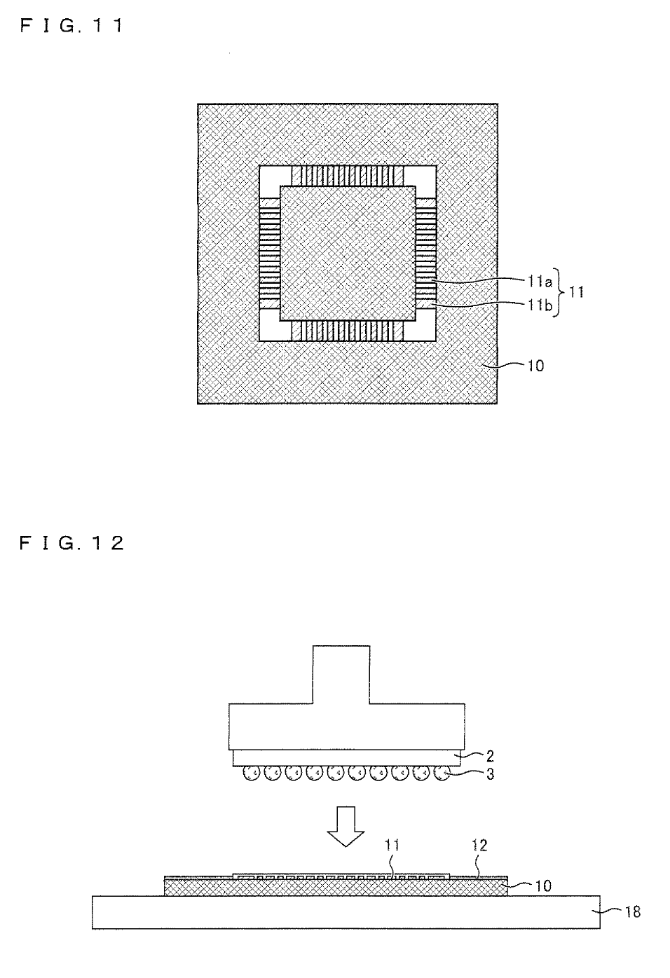

FIG. 11 is a plan view of the substrate 10 on which the wiring patterns 11 are formed. On the substrate 10 of this embodiment, as illustrated in FIG. 11, the wiring patterns 11b at the respective peripheral corner parts of the mounted semiconductor element 2 are formed to have a broader width in comparison to the normal wiring patterns 11a.

Next, an alkali developer is sprayed for development. Since the photoresist 21 at the part chemically changed by the exposure is decomposed (positive method), the development leaves the photoresist 21 on the surface of the substrate 10 in accordance with the wiring patterns 11. As a result, as illustrated in (d) of FIG. 10, a pattern of the photoresist 21 is formed on the metal film 20 on the surface of the substrate 10.

Then, as illustrated in (e) of FIG. 10, the metal film 20 is etched physically or chemically by using the pattern of the photoresist 21 as a mask. For example, it is possible to etch and remove the metal film by putting in a plasma condition.

After the completion of the etching process, the photoresist remained on the formed metal film 20 is removed by ashing process using e.g. oxygen plasma, as illustrated in (f) of FIG. 10. In addition, impurities such as metal and organic matters are removed at the same time by washing with a solution of acid or the like.

At last, as illustrated in (g) of FIG. 10, only the part where soldering is required is exposed as copper foil, and the solder resist 12 such as thermosetting epoxy resin film is formed on the substrate 10 in such a manner that no constituent of the connection electrodes 3 is adhered to the part where the connection electrodes 3 are not to be bonded.

The substrate 10 may be manufactured by going through the above-described processes.

It is to be noted that the manufacturing method of the substrate 10 is not limited to the subtractive process as described above, wherein the circuit is left by removing unnecessary parts from the substrate 10 entirely covered with the metal film 20. For example, it may be manufactured by the additive process, i.e. by adding the wiring patterns 11 to the substrate 10 afterwards.

Now, the bonding method of the semiconductor element 2 and the substrate 10 is described. In the semiconductor device 1, the semiconductor element 2 and the substrate 10 are bonded by the face-down mounting method.

FIG. 12 is a cross-sectional view illustrating the method of mounting the semiconductor element 2 on the substrate 10. First, as illustrated in FIG. 12, the connection electrodes 3 on the connection surface of the semiconductor element 2 are disposed on the wiring patterns 11 on the substrate 10.

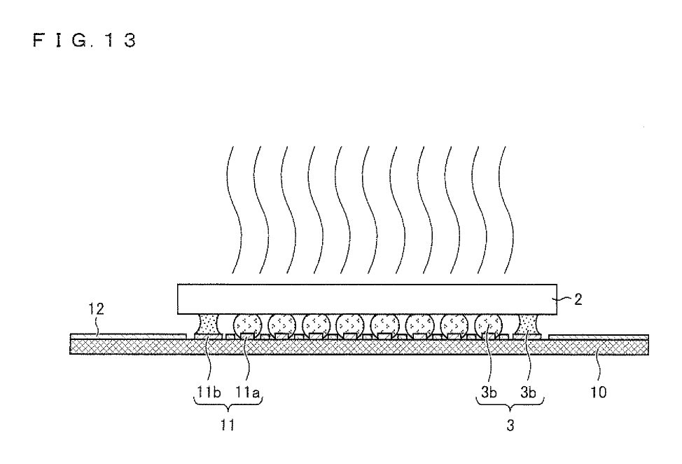

FIG. 13 is a cross-sectional view illustrating a method of bonding the substrate 10 and the semiconductor element 2 by heating method. As a next step, as illustrated in FIG. 13, the connection electrodes 3 on the semiconductor element 2 made of solder or the like are heated and melted by heating through hot air, pulse heat, infra-red radiation or the like, and the wiring patterns 11 and the semiconductor element 2 are bonded by metal bonding.

Here, on the wiring patterns 11b at the peripheral corner parts of the semiconductor element 2, as illustrated in FIG. 13, fillet-shaped connection electrodes 3b are formed. This makes it possible to manufacture the semiconductor device 1 having a superior bonding reliability without increasing processes and components.

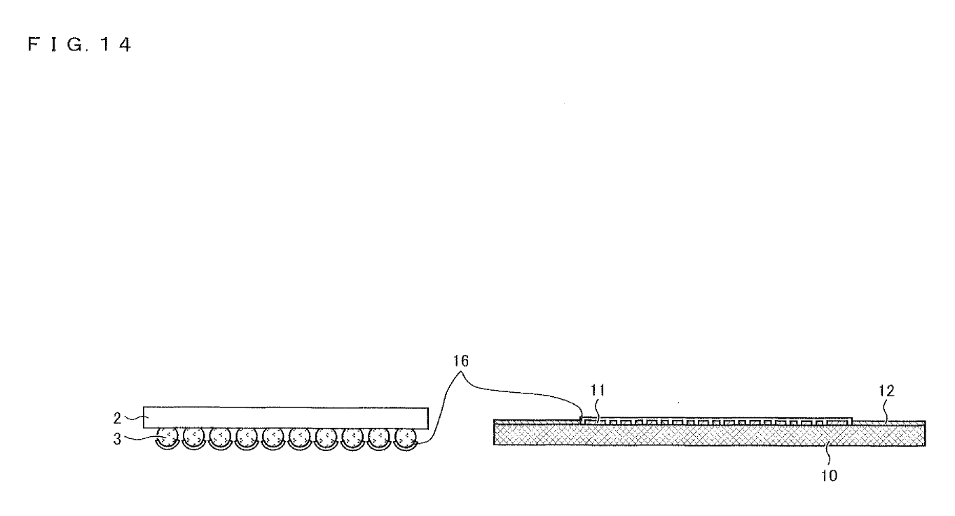

FIG. 14 is a cross-sectional view illustrating the substrate 10 and the semiconductor element 2 to which flux is applied. As illustrated in FIG. 14, the semiconductor element 2 and the substrate 10 may be bonded in such a manner that flux 16 for removing the surface oxide film such as solder is applied in advance to the wiring patterns 11 on the substrate 10 or the connection electrodes 3 by spraying method, transcription method or printing method.

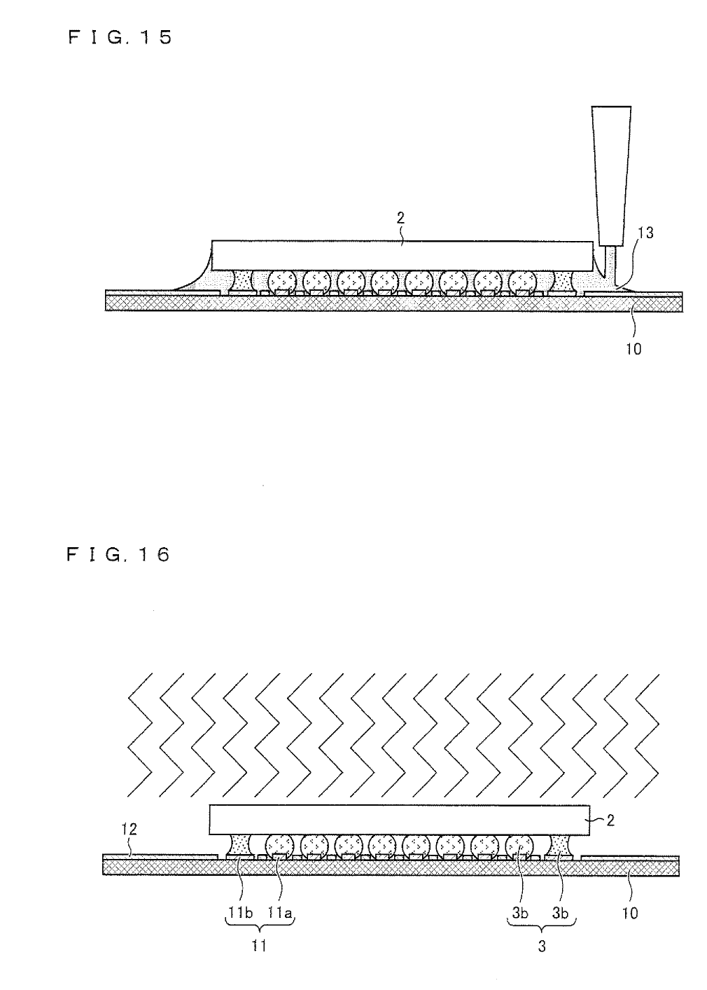

FIG. 15 is a cross-sectional view illustrating a method of filling encapsulation resin between the substrate 10 and the semiconductor element 2. As illustrated in FIG. 15, after the bonding, it is desirable that the encapsulation resin 13 be filled between the semiconductor element 2 and the substrate 10.

FIG. 16 is a cross-sectional view illustrating a method of plasma-processing the substrate 10 and the semiconductor element 2. As illustrated in FIG. 16, when the encapsulation resin 13 is filled, for the purpose of improving the adhesiveness between the encapsulation resin 13 and the substrate 10 as well as between the encapsulation resin 13 and the semiconductor element 2, a physical cleaning process may be performed, wherein the plasma ions generated in advance by a plasma dry cleaner unit (not illustrated) are impacted against the surface of the semiconductor element 2 or the substrate 10 to remove the surface. Also, a chemical cleaning process may be performed, wherein molecules are excited by the plasma dry cleaner unit so that the molecular bonds are cut, and the dissociated radicals are adhered to the surface of the substrate to generate volatile products such as CO₂, H₂O or the like.

The physical cleaning process can roughen the surface of the semiconductor element 2 or the substrate 10, so that the adhesiveness is enhanced due to greater adhering area and anchor effect thereby provided. In addition, the chemical cleaning process can remove contamination caused by organic matters on the surface of the substrate 10, so that the adhesiveness can be improved.

As described above, in the semiconductor device 1 of this embodiment, by configuring the width of the wiring patterns 11b to be greater than the value calculated by the above-mentioned formulas, it is possible to form fillet-shaped connection electrodes 3b on the configured wiring patterns 11b. In addition, as stated above, the configuration of the wiring patterns 11b is not limited to the width of the wiring patterns, but the height of the wiring patterns or the combination of the width and the height may also be configured.

The present invention is not limited to the description of the embodiments above, but may be altered within the scope of the claims. An embodiment based on a proper combination of technical means disclosed in different embodiments is encompassed in the technical scope of the present invention.

### Example 1

Referring to FIGS. 4 and 5, Example 1 describes a case where width of wiring patterns 11b in a semiconductor device 1 is specifically calculated. Here, connection electrodes 3 are made from solder.

In the semiconductor device 1, as illustrated in FIG. 4, the connection electrodes 3 on the connection surface of a semiconductor element 2 are flip-chip mounted on wiring patterns 11 of a substrate 10 in a face-down manner.

As illustrated in FIG. 4, the semiconductor device 1 is configured such that wiring patterns 11b at the peripheral corner parts of the semiconductor element 2 is broader in width than that of the normal wiring patterns 11a according to the above-mentioned formulas, so that fillet-shaped connection electrodes 3b are formed thereon. This makes it possible to form the connection electrodes 3 at peripheral corner parts of the face-down mounted semiconductor element 2 as the fillet-shaped connection electrodes 3b.

These fillet-shaped connection electrodes 3b disposed at the peripheral corner parts can mitigate the stress arising from the difference between the linear coefficients of expansion of the semiconductor element 2 and the substrate 10 and prevent the bond part from breaking.

In order to form the fillet-shaped connection electrodes 3b at the peripheral corner parts of the semiconductor element 2, the semiconductor element 1 is configured such that the width of the wiring patterns 11b at the peripheral corner parts is broad. In order to determine the width of the wiring patterns 11b, first, the volume V1 of the barrel-shaped connection electrode 3a illustrated in (a) of FIG. 5 is calculated as follows, by using the aforementioned Formula 1.

V1=[πh/6×(3a²+3r²+h²)]+[πh′/6×(3b²+3r²+h′²)]=4.798×10⁵ μm³

a: Radius of a top surface of the barrel-shaped connection electrode 3a (radius of the boundary face between the barrel-shaped connection electrode 3a and the semiconductor element 2)=35 μm

b: Radius of a bottom surface of the barrel-shaped connection electrode 3a (radius of the boundary face between the barrel-shaped connection electrode 3a and the wiring patterns 11a)=30 μm

h: Distance from a center of gravity f to the top surface=35.7 μm

h′: Distance from a center of gravity f to the bottom surface=40 μm

r: Radius of the barrel-shaped connection electrode 3a=50 μm

Next, in order to form the connection electrodes 3 at the peripheral corner parts as a fillet shape, radius r′ of the bottom surface of a circular truncated cone having the same volume V1=4.798×10⁵ μm³, radius of the top surface a=35 μm and height h+h′=75.7 μm as the aforementioned barrel-shaped connection electrode is calculated according to the above-mentioned Formula 2 to obtain the value of 54.15 μm.

Thus, by configuring the width of the wiring patterns 11b at the peripheral corner part illustrated in FIG. 4 to be greater than twice the radius r′-54.15 μm, the connection electrode 3 to be bonded to the wiring patterns 11b can be formed as a fillet-shaped connection electrode 3b.

### Example 2

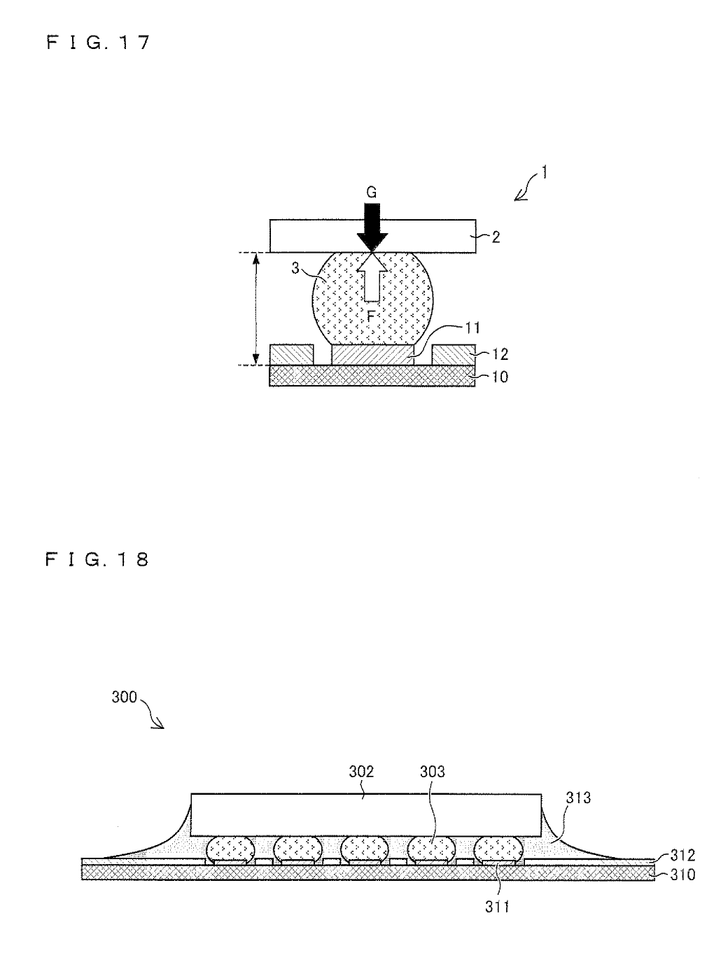

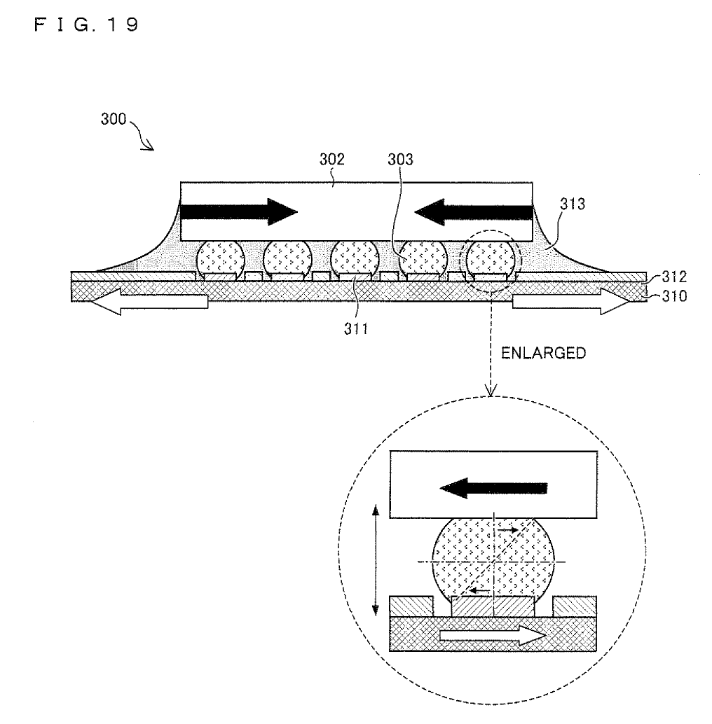

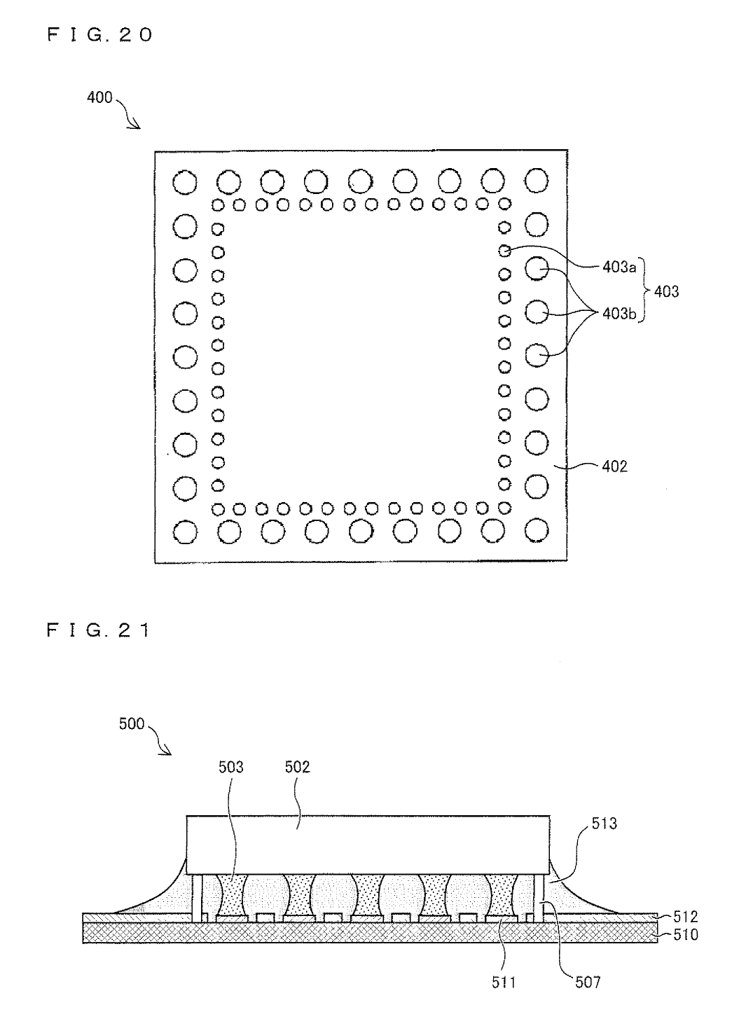

In the Example 2, an occupancy ratio of wiring patterns 11b on which fillet-shaped connection electrodes 3b are formed to the entire wiring patterns 11 is described with reference to FIG. 17. In a semiconductor device 1 of the invention, a part of the wiring patterns 11b is configured by using the aforementioned formula, and thus the semiconductor device 1 is characterized in that the connection electrode formed on the configured wiring patterns 11b is fillet-shaped.

Also in this example, the connection electrodes 3 are made from solder.

FIG. 17 is a partial cross-sectional view illustrating the semiconductor device showing an equilibrium condition between the gravity of the semiconductor element 2 and the surface tension of solder or the like of the bond part. As illustrated in FIG. 17, the equilibrium condition between a gravity G applied to the semiconductor element 2 and a surface tension F of solder or the like determines how large a space between the semiconductor element 2 and the substrate 10 is and which shape the connection electrode 3 has.

Table 1 below shows relation between (i) the occupation ratio of the wiring patterns 11b to the entire wiring patterns 11 in terms of width and (ii) the shape of the connection electrode 3.

TABLE 1

| Number of | | Occupancy ratio of |
|---|---|---|
| patterns at the | | patterns at the |
| periphery/ | Evaluation of appearance | periphery to the entire |
| side | Shape of land at the periphery | wiring patterns |
| 10 | OK: Fillet shape | 12.2% |
| 11 | ↑ | 13.4% |
| 12 | ↑ | 14.6% |
| 13 | ↑ | 15.9% |
| 14 | ↑ | 17.1% |
| 15 | ↑ | 18.3% |
| 16 | ↑ | 19.5% |
| 17 | Approx. Circular truncated | 20.7% |
| | cone | |
| 18 | NG: Barrel shape | 22.0% |
| 19 | ↑ | 23.2% |
| 20 | ↑ | 24.4% |
| 41 | ↑ | 50.0% |

### Samples:

Wafer: 7.3 mm×7.3 mm

Number of solder bumps: 82/side×4 sides

Number of substrate patterns (number of lands): 82×4 sides

Width of patterns at the periphery: 108 μm

Width of other patterns: 60 μm

As shown in the Table 1, when the occupation ratio of the wiring patterns 11b is 20.7 percent, the shape of the connection electrode 3 is a circular truncated cone. That is, when the number of the configured wiring patterns 11b exceeds 20% of the number of the entire wiring patterns 11 formed on the substrate 10, the equilibrium condition between the surface tension F of solder and the gravity G is changed, and the space between the semiconductor element 2 and the substrate 10 becomes narrower. As a result, in some cases, the connection electrodes 3b formed on the wiring patterns 11b having the width calculated by the aforementioned formulas may not be formed to be fillet-shaped.

Therefore, when e.g. solder is used for the connection electrodes 3, according to the aforementioned Table 1 showing the experimental result, the number of the wiring patterns 11b whose width is configured should preferably be equal to or less than 20% of the number of the entire wiring patterns 11 of the semiconductor device 1.

### Overview of Embodiment

In the semiconductor device of this embodiment, where at least one of the other ones of said connection electrodes have a barrel shape, it is preferable that the connection electrodes having the fillet shape be formed by configuring the width of the part of said wiring patterns to be greater than a diameter of a bottom surface of a circular truncated cone identical with the connection electrodes that have the barrel shape, in terms of height, top surface radius, and volume.

According to this structure, the fillet-shaped connection electrodes that are not likely to be affected by stress are easily formed on the wiring patterns whose width is configured to be greater than the diameter of the bottom surface of a circular truncated cone having the same height, radius of the top surface and volume as the barrel-shaped connection electrodes.

Consequently, a semiconductor device with a high bonding reliability can easily be realized.

Moreover, in the semiconductor device of this embodiment, it is preferable that at least one of said connection electrodes having the fillet shape be formed at each peripheral corner part of said semiconductor element.

According to this structure, the fillet-shaped connection electrodes are formed at the peripheral corner parts of the semiconductor device that are likely to be affected by stress the most.

Consequently, a semiconductor device with a higher bonding reliability can be realized.

Additionally, in the semiconductor device of this embodiment, it is preferable that said connection electrodes be made from one material selected from the group consisting of Ni, Cr, Au, Zn, Cu, solder, and lead-free solder or includes layers of two or more materials selected from the group.

According to this structure, connection electrodes having a superior workability and conductive property can be suitably formed.

In addition, the semiconductor device of this embodiment preferably comprises a surface coating material formed on said wiring patterns, the surface coating material being Sn, Au, Ni, Cu, solder, lead-free solder or organic solderability preservative.

According to this structure, oxidation of the wiring patterns and the like can effectively be prevented.

Moreover, in the semiconductor device of this embodiment, it is preferable that the connection electrodes be disposed on said semiconductor element in accordance with a peripheral or an area-array layout.

According to this structure, the bonding reliability of the semiconductor device having a peripheral or an area-array layout can be enhanced.

In addition, the semiconductor device of this embodiment preferably comprises a plurality of the semiconductor elements on one said substrate, wherein the plurality of the semiconductor elements are of the same or different kind.

According to this structure, two or more semiconductor elements of the same or different kind are mounted on one substrate.

As a result, it becomes possible to diversify and downsize the semiconductor device.

Furthermore, in the semiconductor of this embodiment, it is preferable that, in addition to said semiconductor element, discrete electronic components be mounted on said substrate.

According to this structure, it is possible to further diversify the semiconductor device.

In addition, the semiconductor device of this embodiment preferably comprises another semiconductor element which said semiconductor element is bonded to instead of bonding to said substrate.

According to this structure, even in the case where a semiconductor element and another semiconductor element are bonded, it is possible to form on a part of the wiring patterns fillet-shaped connection electrodes that are less likely to be affected by stress.

Moreover, a manufacturing method of a semiconductor device of this embodiment is arranged such that it comprises forming on said substrate the part of said wiring patterns having the width that allows the connection electrodes formed on the part of said wiring patterns to have the fillet shape.

According to this method, because the width of a part of the wiring patterns is configured as described above, a semiconductor device is manufactured, wherein the fillet-shaped connection electrodes that are not likely to be affected by stress are formed on these wiring patterns.

As a result, it becomes possible to manufacture a semiconductor device having a high bonding reliability without involving the increase of raw material, components, processes and the others.

In addition, in the manufacturing method of a semiconductor device of this embodiment, where at least one of the other ones of said connection electrodes have a barrel shape, it is preferable that the step of forming gives the part of said wiring patterns a width greater than a diameter of a bottom surface of a circular truncated cone identical with the connection electrodes that have the barrel shape, in terms of height, top surface radius, and volume.

According to this method, a semiconductor device can be easily manufactured, wherein the fillet-shaped connection electrodes that are not likely to be affected by stress are formed on the wiring patterns whose width is configured to be greater than the diameter of the bottom surface of a circular truncated cone having the same height, radius of the upper surface and volume as barrel-shaped connection electrodes.

Consequently, a semiconductor device with a high bonding reliability can easily be manufactured.

In addition, the manufacturing method of the semiconductor device of this embodiment preferably comprises bonding said connection electrodes and said wiring patterns on said substrate by heating.

According to this method, the connection electrodes and the wiring patterns on the substrate are easily bonded.

The invention being thus described, it will be obvious that the same way may be varied in many ways. Such variations are not to be regarded as a departure from the spirit and scope of the invention, and all such modifications as would be obvious to one skilled in the art are intended to be included within the scope of the following claims.

### INDUSTRIAL APPLICABILITY

The invention can be preferably applied to semiconductor devices having built-in semiconductor elements for use in electronic devices such as information and telecommunication equipments.

1. A semiconductor device in which wiring patterns on a substrate and connection electrodes are electrically connected by face-down mounting, the connection electrodes being made from a conductive material and formed on a connecting surface of a semiconductor element, wherein:
a part of said wiring patterns has such a width that allows the connection electrodes formed on the part of said wiring patterns to have a fillet shape.

2. The semiconductor device according to claim 1, wherein:
at least one of the other ones of said connection electrodes have a barrel shape; and
the connection electrodes having the fillet shape are formed by configuring the width of the part of said wiring patterns to be greater than a diameter of a bottom surface of a circular truncated cone identical with the connection electrodes that have the barrel shape, in terms of height, top surface radius, and volume.

3. The semiconductor device according to claim 1, wherein:
at least one of said connection electrodes having the fillet shape is formed at each peripheral corner part of said semiconductor element.

4. The semiconductor device according to claims 1, wherein:
said connection electrodes is made from one material selected from the group consisting of Ni, Cr, Au, Zn, Cu, solder, and lead-free solder or includes layers of two or more materials selected from the group.

5. The semiconductor device according to claim 1, comprising:
a surface coating material formed on said wiring patterns, the surface coating material being Sn, Au, Ni, Cu, solder, lead-free solder or organic solderability preservative.

6. The semiconductor device according to claim 1, wherein:
said connection electrodes are disposed on said semiconductor element in accordance with a peripheral or an area-array layout.

7. The semiconductor device according to claim 1, comprising:
a plurality of the semiconductor elements on one said substrate, wherein the plurality of the semiconductor elements are of the same or different kind.

8. The semiconductor device according to claim 1, comprising:
a discrete electronic component on said substrate, in addition to said semiconductor element.

9. The semiconductor device according to claim 1, comprising:
another semiconductor element which said semiconductor element is bonded to instead of bonding to said substrate.

10. A method of manufacturing a semiconductor device in which wiring patterns on a substrate and connection electrodes are electrically connected by face-down mounting, said connection electrodes being formed on a connecting surface of a semiconductor element and made from a conductive material, and a part of said wiring patterns having such a width that allows the connection electrodes formed on the part of said wiring patterns to have a fillet shape, the method comprising:
forming on said substrate the part of said wiring patterns having the width that allows the connection electrodes formed on the part of said wiring patterns to have the fillet shape.

11. The method according to claim 10, wherein:
at least one of the other ones of said connection electrodes have a barrel shape; and
the step of forming gives the part of said wiring patterns a width greater than a diameter of a bottom surface of a circular truncated cone identical with the connection electrodes that have the barrel shape, in terms of height, top surface radius, and volume.

12. The method according to claim 10, comprising:
bonding said connection electrodes and said wiring patterns on said substrate by heating.
